(19) United States
(12) Patent Application Publication
(10) Pub. No.: US 2026/0161533 A1
(43) Pub. Date: Jun. 11, 2026

(54) TEST RUNTIME OPTIMIZATION ENABLED BY ARTIFICIAL INTELLIGENCE AND A SMART TEST EXECUTIVE

(71) Applicant: Tektronix, Inc., Beaverton, OR (US)

(72) Inventors: Keith D. Rule, Beaverton, OR (US); Dane Miller, Salt Lake City, UT (US); Madhusudan Acharya, Bengaluru (IN); Nitin Khaneja, Bengaluru (IN); P E Ramesh, Bengaluru (IN); Frederick B. Kuhlman, III, Nashville, TN (US)

(21) Appl. No.: 19/405,104

(22) Filed: Dec. 1, 2025

Related U.S. Application Data
(60) Provisional application No. 63/730,887, filed on Dec. 11, 2024.

(51) Int. Cl. G06F 11/3668

(52) U.S. Cl. CPC G06F 11/3688; G06F 11/3696

(57) ABSTRACT

A test and measurement system includes a test and measurement instrument having one or more ports to connect to one or more devices under test (DUTs), a generative AI model, a user interface to allow a user to provide inputs to the system, and one or more processors to receive a user input identifying a test requirement specification, provide the test requirement specification to the generative AI model. receive a set of prerequisites from the generative AI model, use the set of prerequisites to generate an order for a set of tests for the DUT to minimize hardware changes for testing and minimize data collection instances from the DUT, perform the set of tests according to the order to acquire data from the DUT, and analyze the acquired data from the DUT to determine if the DUT has passed or failed one or more of the tests.

### CROSS-REFERENCE TO RELATED APPLICATIONS

This disclosure is a non-provisional of and claims benefit from U.S. Provisional Application No. 63/730,887, titled “TEST RUNTIME OPTIMIZATION ENABLED BY AI AND A SMART TEST EXECUTIVE,” filed on Dec. 11, 2024, the disclosure of which is incorporated herein by reference in its entirety.

### TECHNICAL FIELD

This disclosure relates to test and measurement systems, and more particularly to systems and methods for optimizing test runtime on a device under test (DUT).

### BACKGROUND

Generally, the process for testing a DUT can be thought of as having two phases. First, creation involves the writing of the test, and second, runtime involves the running of the tests as written. Many proposals have been made for using artificial intelligence (AI) to read specifications and generate test programs. Conventionally, the focus is generally on the code generation portion of this process. FIG. 1 shows an example of a workflow for code generation. The specification is used by the generative AI model to generate code to run the test.

Usually, tests are written once and run many times. Most conventional AI spec-to-code workflows focus on optimizing the first item, the time-to-code generation. However, reducing test runtime is an especially important consideration for test and measurement system customers. Faster tests mean less test time. On the manufacturing line, faster tests mean more throughput. This is often more important than test creation time.

### BRIEF DESCRIPTION OF THE DRAWINGS

FIG. 1 shows an example of a testing workflow employing artificial intelligence (AI).

FIG. 2 shows an embodiment of a testing workflow employing AI.

FIG. 3 shows an embodiment of a generalized test workflow for a testing setup.

FIG. 4 shows an alternative embodiment of a generalized test workflow.

FIG. 5 shows a diagram of an embodiment of a generalized test workflow using prerequisite knowledge.

FIGS. 6A and 6B show a comparison between unoptimized test behavior and optimized test behavior.

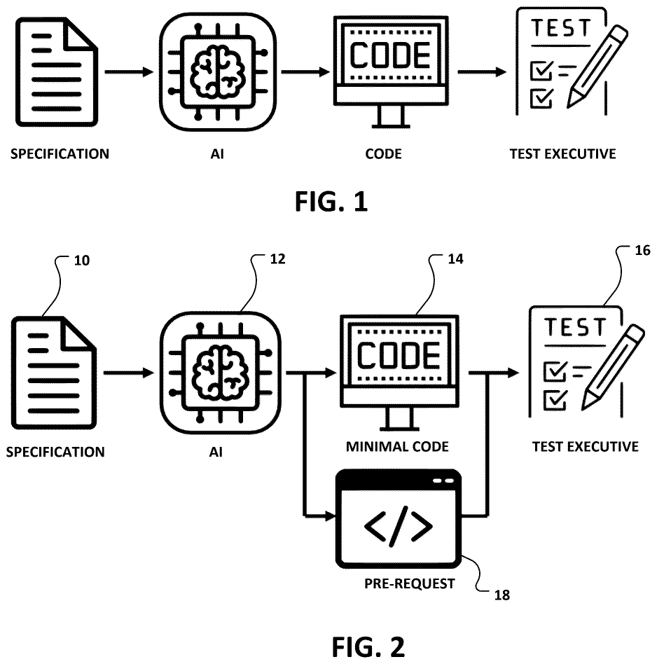

### DETAILED DESCRIPTION

Embodiments of this disclosure involve leveraging code generation to reduce testing time. Beyond just reducing the testing runtime, the embodiments may reduce the number of tests that need to be run, and the amount of data that needs to be required for analysis and determination if the device under test (DUT) has passed the test. Passing a test may mean that the DUT has met the performance requirements set out in a specification, such as for a standard, discussed in more detail later.

The embodiments add AI to the test creation process by utilizing a generative AI model, referred to herein as “AI.” This provides a unique perspective on the user's intent for the test. Using AI allows a form of global optimization currently unavailable to test executives' users. The term “test executive” as used herein means a software program or package that controls the testing process. The test executive may comprise a commercially available software program, or it may involve code written for the test.

The embodiments take a different approach, rather than generating code by rote they allow a test executive to apply many kinds of optimization to a test suite. The process of having the AI read the specification that sets out the requirements that the DUT must meet results in the AI having intimate knowledge of the context in which a test is run. This knowledge is useful for giving a test executive “hints” for optimization and reducing the amount of code required to be generated. The hints may be considered “pre-requests” as shown in FIG. 2. The test specification 10 is provided to the generative AI model (AI) 12. The AI 12 then generates the test code 14 and creates a list of pre-requests 18. These are then handed over to the test executive 16.

The pre-requests provide foreknowledge to the testing executive that certain types of testing setups are needed for both the DUT and the instrument, and that certain types of data are needed for analysis. The data needed for analysis may include particular measurements or other types of data collected as the tests are performed.

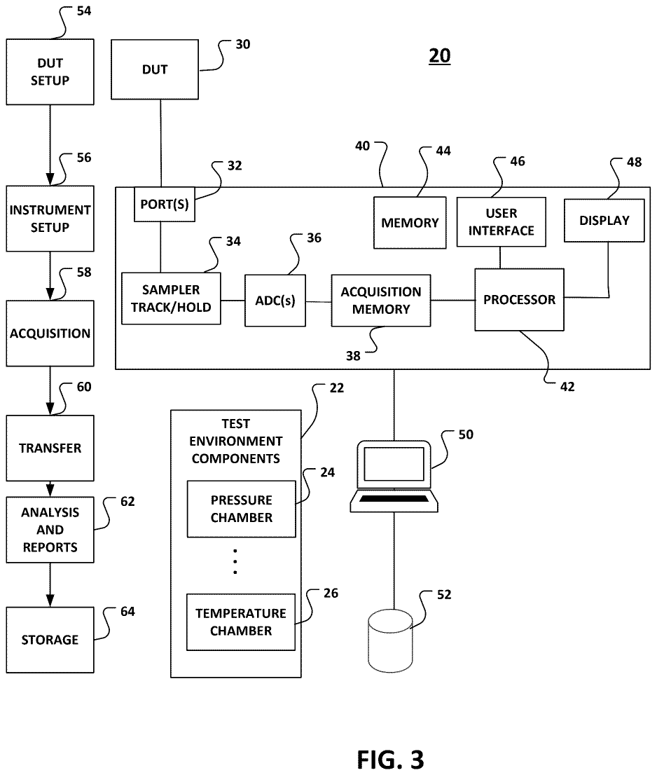

FIG. 3 shows an example of a test and measurement system 20 to be used in a generalized test workflow for a testing setup, according to embodiments of this disclosure. The test and measurement system 20 may contain several different elements that form the testing environment. These may include, but are not limited to, one or more test and measurement instruments such as 40, one or more devices under test (DUTs) 30, other components 22, which may include, but are not limited to, such components as pressure chamber(s) 24, and temperature chamber(s) 26, other computing devices such as 50 separate from the test and measurement instrument, and one or more storage devices such as 52.

The device under test (DUT) 30 needs to be set up or configured as part of the workflow at 54. The DUT can be configured automatically or manually. For automatic configuration, one or more processors resident in the test and measurement system shown in FIG. 3 can configure the DUT. The processors may reside on the one or more test and measurement instruments such as 40, and/or one or more separate computing devices such as 50, which may include a separate computing device to perform analysis, and a computing device that operates the generative AI model. The processors generally are configured to execute code that causes the processor to perform one or more tasks. Similar to the DUT, the test and measurement instrument 40, used to observe and capture signals from the DUT when undergoing testing, may also be configured automatically or manually as part of the workflow at 56. The configuration of the DUT and the instrument occurs in accordance with the test specification 10 in FIG. 2. Also shown in FIG. 2, the test specification is provided to the generative AI model.

After set up/configuration, the workflow proceeds to acquiring the signal in the form of digital data at 58. Instrument 40 receives signals from the DUT through one or more ports 32, which may include probes, optical to electrical converters, etc. The signal is sent to a sampler track and hold circuit 34. The track and hold circuit 34 holds each signal steady for a period of time sufficient to enable acquisition by one or more high-resolution analog-to-digital converters (ADC) 36. The analog-to-digital converter (ADC) 16 converts the analog signal from the track and hold circuit 34 to a digital signal. The one or more ADCs 36 will generally comprise high-speed ADCs. The digitized signal from the ADCs 36 can then be stored in an acquisition memory 38. The instrument may also have other memory 44 besides the acquisition memory 38. Memory 44 may store program instructions for the one or more processors 42, as well as other data as needed.

User inputs are received from the user interface 46 and coupled to the one or more processors 42. User interface 46 may include a keyboard, mouse, trackball, touchscreen, and/or any other controls employable by a user to interact with a GUI on display 48. Display 48 may be a digital screen, or any other monitor to display waveforms, measurements, and other data to a user. The display and the user interface may comprise a single device, such as a touch screen that allows user inputs, or the user interface may be combination of the touch screen and other input devices mentioned above.

One or more processors 42 may be configured to execute instructions from memory and may perform any methods and/or associated steps indicated by such instructions, such as receiving the acquired signals from the acquisition memory 38 and reconstructing the signal under test from samples generated by the ADCs.

While the components of the test and measurement instrument 40 are depicted as being integrated within a single instrument, it will be appreciated by a person of ordinary skill in the art that any of these components can be external to the instrument 40 and can be coupled to the instrument 40 in any conventional manner (e.g., wired and/or wireless communication media and/or mechanisms).

In some instances, discussed in more detail below, the data may be transferred to a computing device 50 separate from the instrument 40. The conditions under which that transfer may occur are discussed in more detail below.

The test specification 10 is provided to the generative AI model 12. Identifying the test specification may result from a user input either to the instrument 40 or the computing device 50. In some embodiments, the AI 12 may reside on computing device 50, or in some cases on a network to which computing device 50 is connected. In other embodiments, as processing speeds and computing power continue to increase, the instrument may contain the AI 12 and/or the data analysis capacity. The instrument will operate to perform tests on the DUT to allow acquisition of data from the DUT at 58 to be analyzed in light of the test specification at 62. The results and/or the data may then be stored at 64 in the storage 52.

Many defined tests exist, which could be many hundreds of tests. Each needs to be executed and its results interpreted. This is usually done by a test executive, which can be a commercial product or, more often, ad hoc code built for this purpose, as mentioned above. Writing code this way does not allow for much optimization. Any given test will not be generally aware of other tests, so sharing work already done between tests is not feasible.

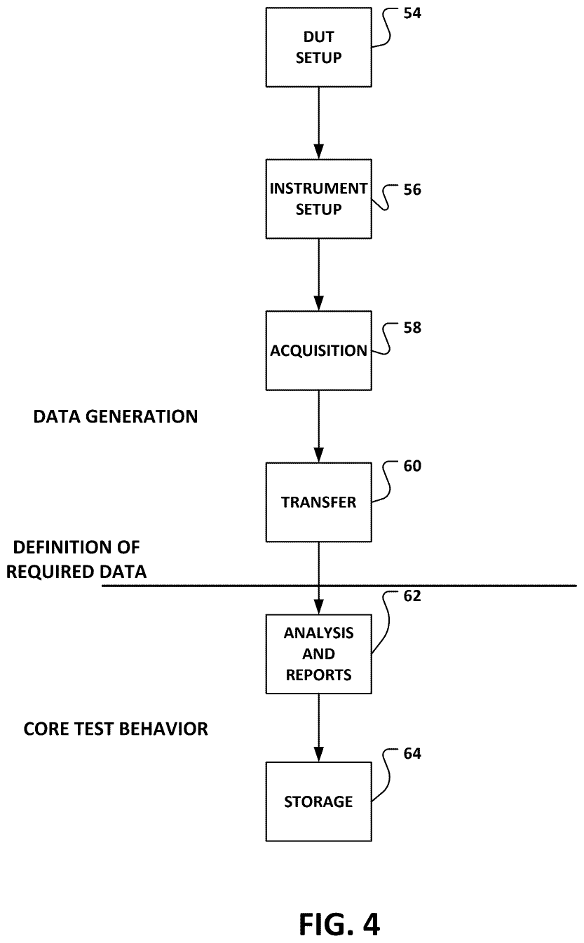

FIG. 4 shows a flowchart of the testing workflow, but with an alternative view. This view divides the problem into two parts, that of data generation, and test behavior. The data generation portion contains the DUT setup at 54, the instrument setup at 56, data acquisition from the DUT at 58, and, if needed, the data transfer at 60, based upon connection speeds, as discussed below. The core test behavior comprises the analysis as reports at 62 and the storage of the test parameters, specification, data, results, etc., at 64.

The definition of the required data describes the data required by the test behavior and links the two parts. This discussion refers to that data as a “prerequisite” for running the test behavior in this case. Having AI read the test specification will allow the AI to define the types needed for these ‘prerequisites.’

As an example for ease of understanding, assume the user had identified that the testing is to be done under the DisplayPort 1.2 specification. The specification defines the set of ‘prerequisites’ to be selections from: Bit Rate: 1.62, 2.7 Gb/s; Pattern type: None, D10.2, PRBS 7, Symbol Error Rate pattern; Pre-Emphasis: 0, 3.5, 6, and 9.5 dB; Differential Levels: 400, 600, 800, or 1200 mV; and Lane: one, two, or four lanes (specifically, which sets of lanes). The DUT and the instrument would be set up in accordance with that specification. In addition, a test will define other aspects of the required data. These usually influence how the data is acquired and may include but are not limited to record length, number of unit intervals, and a population of specific signal patterns, as examples of the types of required data. The knowledge of what is to be tested, and the requirement would inform the test executive as to the order to be used for the testing to minimize the test time.

Regardless, the specification defines the set of ‘prerequisites’ that specify the key properties of the data provided for an individual test. The prerequisites apply to the DUT and the instruments involved. There is a direct mapping of prerequisites to both DUT and instrument settings that can be derived automatically.

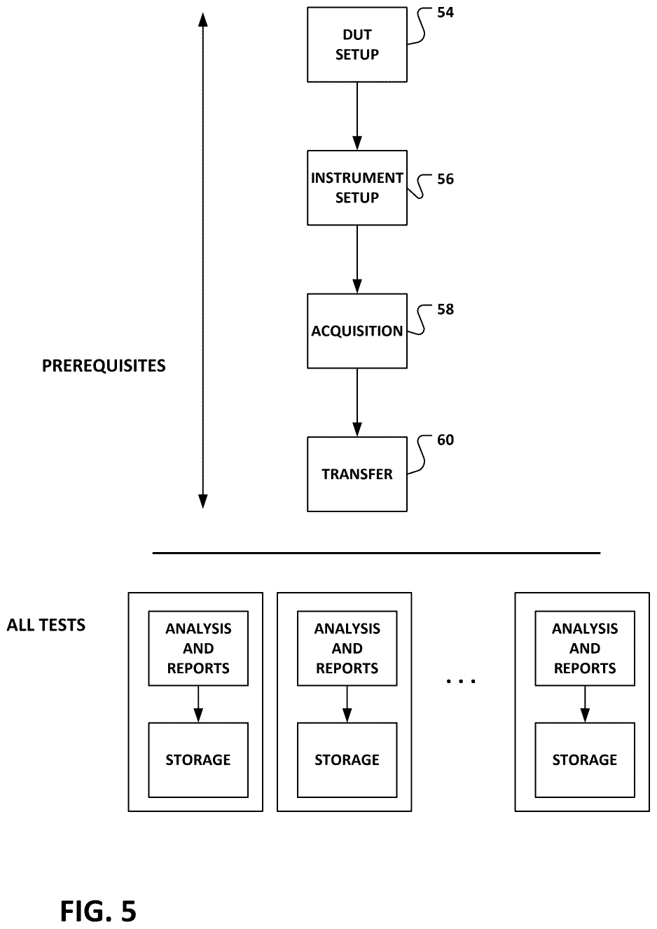

Further, storing ‘prerequisites’ allows comparison of ‘prerequisites. This means one can notice when a prerequisite is used for multiple tests. The result of having prerequisites is that test execution can be viewed as shown in FIG. 5. As shown in FIG. 5, the prerequisites completely define the setup of data generation, from DUT set up to acquisition, and transfer if used. This allows data to be collected and reused. This represents an advantage because data collection is an expensive process, for example in terms of time, signal acquisition resources, and processing resources.

Using prerequisites to define the testing behavior allows for parallelization of operations that previously were not parallelizable. Generally, analysis will be run outside the data collection phase to parallelize it. This means optimization will probably most likely occur when the analysis is done off the instrument 40 and by a separate computing device 50. This does not preclude some optimization if analysis runs on the instrument itself. As mentioned above, with the increase in computing power, the instrument may handle all of the related tasks. Typically, though, keeping the analysis on the instrument will preclude using parallelism. The analysis system should be componentized to achieve maximum performance.

Further, as indicated above regarding connection speeds, scheduling the best performance might be a function of the testing environment. If the connection between the instrument and the external computing device has a bandwidth of 10 Gbe and a high-speed connection is used, then pulling data off to parallelize analysis makes sense. In contrast, if the connection runs on a 100 Mbe network, moving the data off might never make sense. The Test Executive should be aware of the environment and optimize the schedule accordingly. However, this view of how data moves gives more opportunities for optimization.

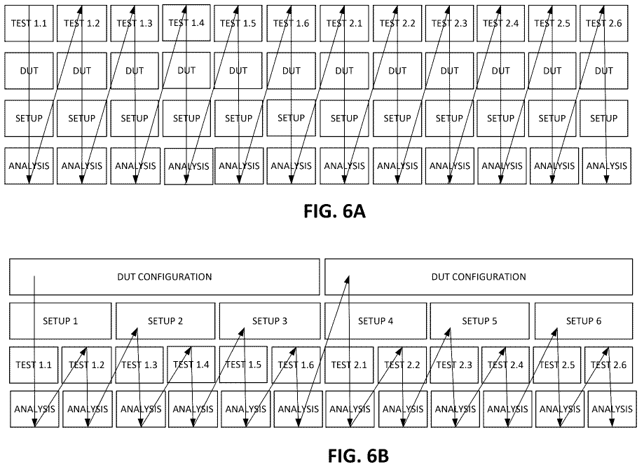

The fact that AI is extracting text information means that it could significantly simplify and abstract what it needs to do by extracting the signal definitions used by the test, as seen above, and providing that information to a prerequisite-aware Test Executive. The net effect is that the Test Executive can easily move from an unoptimized set of behaviors to a more optimized set, as illustrated in FIG. 6A and FIG. 6B.

Most test sequencers work in an unoptimized fashion. The optimization approach shown here, according to embodiments of the disclosure, significantly reduces the number of DUT configurations and changes to the instrument. In FIG. 6B, one should note the black lines between Setup and Test/; these are waveforms that the subsequent tests can share. This significantly reduces the overall work (and total test time) and allows for parallelization of actions that previously could not be done in parallel.

FIG. 6A shows an unoptimized testing operation. Each test includes configuring the DUT, setting up the instrument, performing the test, and then analyzing the results. As an example, using the prerequisites to identify what tests and what data can be shared, the DUT configuration only needs to be changed once, and each DUT configuration only needs to be set up three times to perform 6 tests. As shown in FIG. 6B, those two elements allow for performance of six tests. Just as an example, the DUT is configured twice instead of twelve times, the instrument setup is performed six times instead of twelve, and the tests are performed in an order that allows those reductions.

The previous examples assumed optimization was a function of dependency order. However, this does not consider the cost of change and other factors which the test executive should also consider. Returning to the test environment 20 of FIG. 3, some aspects of setting up the environment might include things other than the instruments or the DUT. This can consist of other components 22, such as pressure chambers 24, temperature chambers 26, etc. For example, changing pressure generally takes longer than changing temperature, and both take far longer than changing settings on DUTs or other test and measurement instruments.

Knowing, or predicting, the time these elements take to reach requested test settings, a cost-of-change allows them to be optimized. Items that take longer need to have their changes minimized first. The same general methodology can be used as described above for testing measurements. Adding pressure and temperature to the list of prerequisites, plus knowing the cost of attaining each setting, means that longer settling time device changes are minimized before shorter settling devices.

Previously, priority optimization, DUT vs. switch vs. instrument, was done by noting dependency order. In a case where dependency is equal, such as a chamber that changes both pressure and temperature, the priority order is chosen by the speed of the rate of change and the required attainment value. A slower rate of changes over a desired range is usually minimized first, meaning that in this example, pressure changes are minimized, and then temperature changes are minimized. The goal is always to minimize the total setup time.

However, even this view might be overly simplistic. For example, if temperature change attainment was slower at lower pressures, then a minimization strategy for pressure and temperature changes might have to do more detailed modeling to determine the optimal order to minimize total time.

This type of optimization is enabled by adding additional properties, like rate of change estimates to setting changes, of environment components. This allows the Test Executive additional opportunities to optimize overall test time. This information would not necessarily come from the AI but would be associated with descriptions of the change settings of the components involved. These cost-of-change estimates may be added to instrument settings. If this information were available for different instruments, then this would allow various combinations of instruments to be analyzed for typical test time estimates. That might allow a user to pick the best set of instruments and devices for a test by estimating the overall test time based on optimized cost-of-change estimates.

Additional aspects of the test environment that can be considering in the optimization process may also include minimizing wear and tear on connectors, cables, and other accessories used in the test equipment, and also optimization for sensitivity for thermal settling, such as most sensitive tests being arranged to run last.

A prerequisite-aware Test Executive has unique, fundamental properties. These include that prerequisites are instrument agnostic meaning tests built this way can run against compatible test hardware with appropriate translation. U.S. Pat. App. Pub. No. 2018/0356445, published Dec. 13, 2018, the contents of which are hereby incorporated by reference into this disclosure in their entirety, describes systems and methods that use measurement “preconditions” in making valid measurements. The Test Executive disclosed herein generally maps these preconditions into prerequisites to expand the use of these preconditions into a broader test optimization context.

The embodiments herein allow for optimizing in different ways, such as minimizing test time, minimizing DUT interaction, test debugging, as examples. The embodiments can consider the rate of change for settings and the cost of moving data in its optimization considerations. This means optimization will adapt to each test environment, resulting in the best outcome for that environment.

Further, the embodiments can provide some interactivity and allow users to inquire about such this as test times given a set of instruments and environmental considerations. It could answer questions like “What will a 10 Gbe lab network buy me?” or ‘How will a Tek 7 Series DPO and a Keysight MXR perform for this test suite?’ Answering questions like this will help choose where to invest in development to consistently outperform competitors in time to test.

In summary, in some example embodiments of this disclosure, an updated AI workflow used to read specifications and create test programs is modified as follows. The embodiments use a modified AI workflow spec-to-code generation process. Pre-requisites are saved as part of the workflow that defines the data properties needed for each test. Only the code required to perform the analysis and interpret the results needs to be generated. This significantly reduces the code required for a test.

A Test executive can be written that uses an instrument-agnostic prerequisite to set up the environment and create the data required for the test. Then, that data can be fed into the corresponding code needed to evaluate the test's status. Given this arrangement, comparing prerequisites to reuse data and parallelize analysis is possible.

Matching can be a bit fuzzy, meaning partial matches that are inclusive may be reused. An example would be where all preconditions match except record length. Generally, longer record lengths can be used when shorter is requested by providing a subset, which is a less expensive operation. Other similar fuzzy matches can also be used. Instruments and devices may also contain the rate of change estimates. The test executive can use these as input to the optimization strategy. This information might also include LAN bandwidth, instrument and offline analysis performance, and other considerations for scheduling test runs. This would allow the test executive to ensure the best environmental performance is achieved

The embodiments provide advantages, such as faster test times. Customers often choose vendors based on test speed. The embodiments allow for a unique level of optimization. This level of optimization has not been used by any existing products of which the inventors are aware. The embodiments generate less code, which is better for AI training and quality. Less code generally means fewer opportunities for bugs. The embodiments are instrument agnostic. Prerequisites define what the signal needs to look like rather than how it is done. It is possible to convert those prerequisites into DUT and instrument settings automatically.

In addition, the embodiments provide automatic input validation. Knowing the signal prerequisites allows validation that the input data requirements are met. It can be important to notice when test devices do not conform to a standard in the data sets they create. In that case, an otherwise passing test would need to be noted as non-compliant, or it would indicate that a manual configuration of the DUT had not been completed successfully. The embodiments also provide a broad feature set for a test executive. This approach allows a better set of features in a companion test executive. It allows the Test Executive to have observability of how to minimize hardware setting changes and where it can reuse data. This enables significantly less instrument setup time and provides an opportunity for parallelization where none previously existed. The net result is a substantial decrease in test time. The embodiments may help customers choose better solutions by estimating test times given different lab conditions and instrument choices. It can also estimate manufacturing throughput at a test station before it is built.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement system, comprising: a test and measurement instrument having one or more ports to allow the instrument to connect to one or more devices under test (DUTs); a generative AI model; a user interface to allow a user to provide inputs to the system; and one or more processors configured to execute code that causes the one or more processors to: receive a user input identifying a test requirement specification; provide the test requirement specification to the generative AI model; receive a set of prerequisites for testing from the generative AI model; use the set of prerequisites to generate an order for a set of tests to be performed on the DUT, the order to minimize hardware changes for testing and minimize data collection instances from the DUT; perform the set of tests on the DUT according to the order to acquire data from the DUT; and analyze the acquired data from the DUT to determine if the DUT has passed or failed one or more of the tests from the set of tests.

Example 2 is the test and measurement system of Example 1, wherein the one or more processors are further configured to execute code to cause the one or more processors to configure the DUT for testing.

Example 3 is the test and measurement system of either of Examples 1 or 2, wherein the one or more processors are further configured to execute code to cause the one or more processors to configure the test and measurement instrument for testing.

Example 4 is the test and measurement system of any of Examples 1 through 3, wherein the one or more processors are further configured to execute code to cause the one or more processors to set up a testing environment.

Example 5 is the test and measurement system of Example 4, wherein the code that causes the one or more processors to set up a testing environment comprises code to cause the one or more processors to adjust the order based upon times for changing settings on at least one component of the testing environment.

Example 6 is the test and measurement system of Example 5, wherein the at least one component of the testing environment includes at least one of a pressure chamber and a temperature chamber.

Example 7 is the test and measurement system of any of Examples 1 through 6, wherein the code that causes the one or more processors to analyze the acquired data from the DUT comprises code that causes the one or more processors to determine data transfer capabilities in the test and measurement system.

Example 8 is the test and measurement system of Example 7, wherein the processors are further configured to transfer the data from the test and measurement instrument to allow the data to be analyzed in parallel based upon the data transfer capabilities within the test and measurement system.

Example 9 is the test and measurement system of any of Examples 1 through 8, wherein the generative AI model comprises a generative AI model trained to generate a set of prerequisites for testing from an input test requirement specification.

Example 10 is a method, comprising: receiving a user input identifying a test requirement specification; providing the test requirement specification to a generative AI model; receiving a set of prerequisites for testing from the generative AI model; using the set of prerequisites to generate an order for a set of tests to be performed on a device under test (DUT), the order to minimize hardware changes for testing and minimize data collection instances from the DUT; performing the set of tests on the DUT according to the order to acquire data from the DUT; and analyzing the acquired data from the DUT to determine if the DUT has passed or failed one or more of the tests from the set of tests.

Example 11 is the method of Example 10, further comprising configuring the DUT for testing.

Example 12 is the method of either of Examples 10 or 11, further comprising configuring the test and measurement instrument for testing.

Example 13 is the method of any of Examples 10 through 12, further comprising setting up a testing environment.

Example 14 is the method of Example 13, wherein setting up a testing environment comprises adjusting the order based upon times for changing settings on at least one component of the testing environment.

Example 15 is the method of Example 14, wherein the at least one component of the testing environment includes at least one of a pressure chamber and a temperature chamber.

Example 16 is the method of any of Examples 10 through 15, wherein analyzing the acquired data from the DUT comprises determining data transfer capabilities of a test and measurement instrument used to perform the tests on the DUT.

Example 17 is the method of Example 16, further comprising transferring the data from the test and measurement instrument to allow the data to be analyzed in parallel.

Example 18 is the method of any of Examples 10 through 17, further comprising training the generative AI model to generate a set of prerequisites for testing from an input test requirement specification.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement system, comprising:
a test and measurement instrument having one or more ports to allow the instrument to connect to one or more devices under test (DUTs);
a generative AI model;
a user interface to allow a user to provide inputs to the system; and
one or more processors configured to execute code that causes the one or more processors to:
receive a user input identifying a test requirement specification;
provide the test requirement specification to the generative AI model;
receive a set of prerequisites for testing from the generative AI model;
use the set of prerequisites to generate an order for a set of tests to be performed on the DUT, the order to minimize hardware changes for testing and minimize data collection instances from the DUT;
perform the set of tests on the DUT according to the order to acquire data from the DUT; and
analyze the acquired data from the DUT to determine if the DUT has passed or failed one or more of the tests from the set of tests.

2. The test and measurement system as claimed in claim 1, wherein the one or more processors are further configured to execute code to cause the one or more processors to configure the DUT for testing.

3. The test and measurement system as claimed in claim 1, wherein the one or more processors are further configured to execute code to cause the one or more processors to configure the test and measurement instrument for testing.

4. The test and measurement system as claimed in claim 1, wherein the one or more processors are further configured to execute code to cause the one or more processors to set up a testing environment.

5. The test and measurement system as claimed in claim 4, wherein the code that causes the one or more processors to set up a testing environment comprises code to cause the one or more processors to adjust the order based upon times for changing settings on at least one component of the testing environment.

6. The test and measurement system as claimed in claim 5, wherein the at least one component of the testing environment includes at least one of a pressure chamber and a temperature chamber.

7. The test and measurement system as claimed in claim 1, wherein the code that causes the one or more processors to analyze the acquired data from the DUT comprises code that causes the one or more processors to determine data transfer capabilities in the test and measurement system.

8. The test and measurement system as claimed in claim 7, wherein the processors are further configured to transfer the data from the test and measurement instrument to allow the data to be analyzed in parallel based upon the data transfer capabilities within the test and measurement system.

9. The test and measurement system as claimed in claim 1, wherein the generative AI model comprises a generative AI model trained to generate a set of prerequisites for testing from an input test requirement specification.

10. A method, comprising:
receiving a user input identifying a test requirement specification;
providing the test requirement specification to a generative AI model;
receiving a set of prerequisites for testing from the generative AI model;
using the set of prerequisites to generate an order for a set of tests to be performed on a device under test (DUT), the order to minimize hardware changes for testing and minimize data collection instances from the DUT;
performing the set of tests on the DUT according to the order to acquire data from the DUT; and
analyzing the acquired data from the DUT to determine if the DUT has passed or failed one or more of the tests from the set of tests.

11. The method as claimed in claim 10, further comprising configuring the DUT for testing.

12. The method as claimed in claim 10, further comprising configuring the test and measurement instrument for testing.

13. The method as claimed in claim 10, further comprising setting up a testing environment.

14. The method as claimed in claim 13, wherein setting up a testing environment comprises adjusting the order based upon times for changing settings on at least one component of the testing environment.

15. The method as claimed in claim 14, wherein the at least one component of the testing environment includes at least one of a pressure chamber and a temperature chamber.

16. The method as claimed in claim 10, wherein analyzing the acquired data from the DUT comprises determining data transfer capabilities of a test and measurement instrument used to perform the tests on the DUT.

17. The method as claimed in claim 16, further comprising transferring the data from the test and measurement instrument to allow the data to be analyzed in parallel.

18. The method as claimed in claim 10, further comprising training the generative AI model to generate a set of prerequisites for testing from an input test requirement specification.
